(19) United States
(12) Patent Application Publication
(10) Pub. No.: US 2009/0084155 A1
(43) Pub. Date: Apr. 2, 2009

(54) Method to Form Pin Having Void Reducing Pin Head and Flattening Head to Perform the Method

(76) Inventors: Ryan Chase, Mesa, AZ (US); Ravi K. Nalla, Chandler, AZ (US)

Correspondence Address: INTEL/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/864,260

(22) Filed: Sep. 28, 2007

(51) Int. Cl. B21D 22/00; B21D 31/00; C21D 9/00; C22F 1/00

(52) U.S. Cl. 72/476; 72/362; 148/559; 29/874; 72/419

(57) ABSTRACT

A method of forming a pin adapted to be used in a PGA joint, and a flattening head used to perform the method. The method includes: providing a pin blank; and forming a pin head by coining an end of the pin blank using a flattening head thereby forming the pin, the pin having a pin stem and the pin head attached to the pin stem, the flattening head being shaped to impart a topography to an underside surface to the pin head that is non-smooth during coining, the topography being adapted to allow gases to escape from a pin-attach solder disposed adjacent to the underside surface.

### FIELD

Embodiments of the present invention relate generally to methods of forming pins for pin grid array package substrates.

### BACKGROUND

Pin grid array (PGA) packages are well known in the art. During flip chip (C4) attach of a microelectronic die to a substrate including a PGA thereon, a reflow process typically occurs at high temperatures, for example, at about 230 degrees Celsius to join lead-free C4 solder bumps on the PGA substrate to conductive bumps, typically Cu bumps, on the die. The reflow process softens and melts not only the solder bumps on the PGA substrate, but also the solder, such as SnSb that is typically used to attach the pins of the PGA to lands on the package substrate (hereinafter “pin-attach solder”). In addition to a softening of the pin-attach solder reflow of the solder bumps on the PGA substrate volatile material trapped in the pin-attach solder tends to vaporize and, along with any air voids trapped in the pin-attach solder, try to escape from the same. A softening of the pin-attach solder and movement of the vaporized volatile material and the voids created thereby during reflow contribute to movement of the pins and can cause a tilting of the pins supported by the pin-attach solder. The above problem is exacerbated as pins are getting smaller and therefore lighter, and as pin count and density increases.

The above problem is also exacerbated by the use of lead free C4 solder metallurgy and nickel-palladium-gold (NiPdAu) based surface finishing. Specifically speaking, the increase of the melting point of lead-free flip-chip solder (e.g., tin-silver, tin-silver-copper solders) relative to previously widely used eutectic tin-lead (SnPb) solder requires the peak temperature of a typical die attachment process to be about 230 degrees Celsius, which overlaps the melting range of the pin-attach solder. As a result, a softening of the pin-attach solder occurs during flip-chip attach, which may result in up to about 20% pin tilt failure of assembled packages. A second aspect of the problem is that, as compared with a pairing of SnSb with ENIG surface finish, SnSb displays poorer wetting interaction with NiPdAu surface finish, which may result in more solder voiding entrapment under the pins. Limited cross-sectional observations show about 30% of pins in such a situation as having voids greater than 200 microns. The presence of such large voids can result in mechanically weak PGA joints as well as in pin movement during chip attach.

FIGS. 1a-1d show stages in the fabrication of a pin for a PGA joint according to the prior art. As seen in FIG. 1a, the prior art provides pin blanks 10 typically cut from a pin wire. As seen in FIG. 1b, a pin blank 10 is then placed in a support jig 12 and aligned to be coined by a flattening head 14. As seen in FIG. 1b-1c, the flattening head 14 is then used to coin a top portion 16 of the pin blank into a flat pin head portion 18. As seen in FIGS. 1b-1d, the prior art method described above results in a pin 11 having a pin stem 13 and a pin head 18.

Referring next to FIG. 1e, a PGA joint formed according to the prior art is shown using pin 11 of FIG. 1d. In FIG. 1d, a side view is shown of one of pin 11 in a tilted state after C4 die attachment. The pin 11 is shown as being mounted onto substrate 5. The pin head 18 is shown as being mounted onto a land pad 8 on a PCB-side surface 6 of substrate 5 using a pin-attach solder joint 15 as shown. As seen in FIG. 1e, the pin-attach solder joint 15 includes voids therein which have tilted the pin 11 for the reasons explained above, thus weakening the electrical and mechanical bond between pin 11 and land pad 8.

The prior art attempts to address the problem of pin tilt include reducing the reflow temperature in order to control a softening of the pin-attach solder and a movement of vaporized volatile material therein. Doing so has shown to improve pin tilt yields, but, disadvantageously, requires very accurate control of the C4 die attach process, even during high volume manufacturing, and further increases the risk for non wets/de-wets on the die to substrate interconnection. The above method may cause insufficient solder joint strength and more void entrapment during C4 die attach simply because a lower peak temperature can jeopardize the process window for C4 attach.

The prior art fails to provide an effective method of minimizing pin tilt during flip chip attach of a die to a PGA substrate.

### BRIEF DESCRIPTION OF THE DRAWINGS

FIGS. 1a-1d are schematic, side cross sectional views of respective stages of a prior art method of forming a pin head;

FIG. 1e is a schematic, side cross sectional view of a PGA joint including a pin formed according to the stages of FIGS. 1a-1d;

FIGS. 2a-2d are schematic side cross sectional views of respective stages of a method embodiment of forming a pin head;

FIG. 2e is a schematic side cross sectional view of a PGA joint including a pin formed according to a method embodiment; and

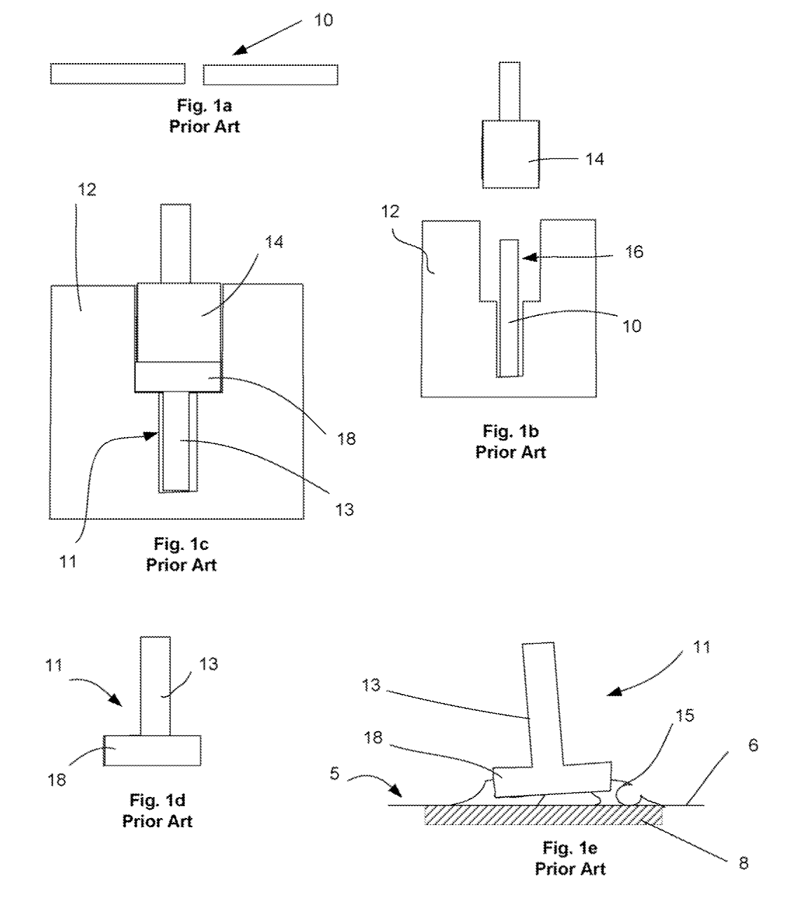

For simplicity and clarity of illustration, elements in the drawings have not necessarily been drawn to scale. For example, the dimensions of some of the elements may be exaggerated relative to other elements for clarity. Where considered appropriate, reference numerals have been repeated among the drawings to indicate corresponding or analogous elements.

### DETAILED DESCRIPTION

In the following detailed description, a method of making a pin adapted to be used in a PGA joint and a flattening head used to perform the method, are disclosed. Reference is made to the accompanying drawings within which are shown, by way of illustration, specific embodiments by which the present invention may be practiced. It is to be understood that other embodiments may exist and that other structural changes may be made without departing from the scope and spirit of the present invention.

The terms on, above, below, and adjacent as used herein refer to the position of one element relative to other elements. As such, a first element disposed on, above, or below a second element may be directly in contact with the second element or it may include one or more intervening elements. In addition, a first element disposed next to or adjacent a second element may be directly in contact with the second element or it may include one or more intervening elements.

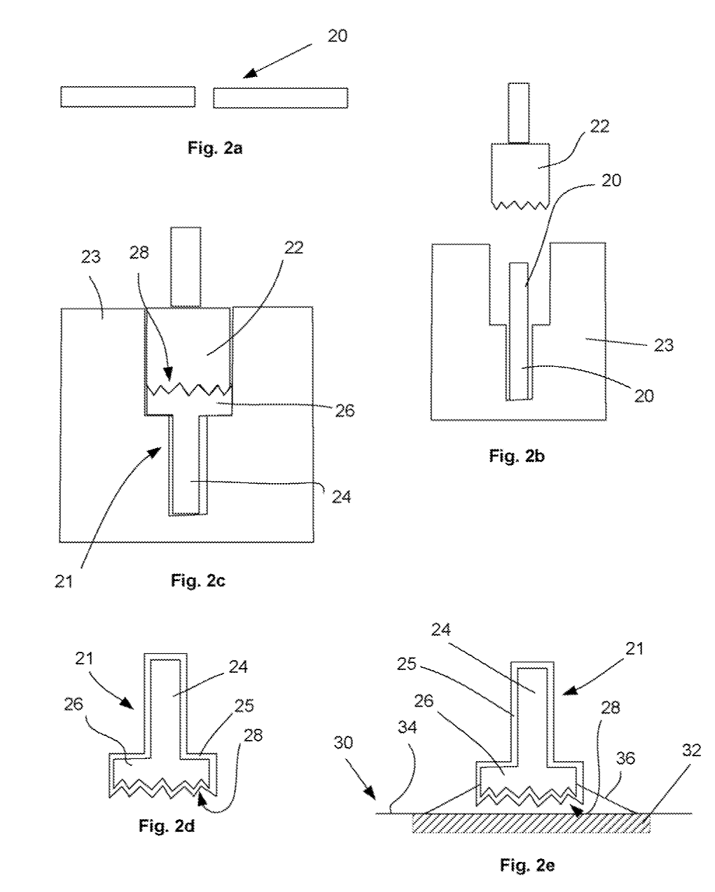

Aspects of this and other embodiments will be discussed herein with respect to FIGS. 2a-2e. The figures, however, should not be taken to be limiting, as it is intended for the purpose of explanation and understanding.

As seen in FIG. 2a by way of example, a method embodiment includes providing pin blanks 20. The pin blanks 20 may be obtained, for example, by cutting a pin wire made of a conductive metal, as would be recognized by one skilled in the art.

Referring next to FIG. 2b-2d by way of example, a method embodiment includes forming a pin head by coining an end of the pin blank 20 using a flattening head, such as flattening head 22, in conjunction with a conventional support jig 23. As shown in FIGS. 2b-2d, the pin 21 thus formed, shown more particularly in FIG. 2d, may have a pin stem 24 and a pin head 26 attached to the pin stem 24. According to embodiments, the flattening head may be shaped to impart, during coining, a topography to an underside surface of the pin head that is non-smooth, where the topography is adapted to allow gases to escape from a pin-attach solder disposed adjacent the underside surface, such as in a PGA joint including the pin. By “underside surface” of the pin head, what is meant in the context of embodiments is a surface of the pin head extending in a direction that has a component adapted to extend parallel to a surface of the land pad of the substrate to which the pin head is to be attached. A topography of the underside surface of a pin head according to embodiments allows “gases to escape from a pin-attach solder adjacent the underside surface” as noted above when the pin head is shaped such that any volatilized materials in the pin attach solder, or any air voids in the pin attach solder, can escape from the pin attach solder adjacent the underside surface. The topography according to embodiments is “non-smooth”. By “non-smooth,” what is meant in the context of embodiments is a surface having a roughness characterized by a peak to valley distance of at least about 50 microns. According to method embodiments, it is the coining operation as performed by the flattening head that imparts topography to the pin head. In particular, as shown in FIGS. 2b-2d, the flattening head 22 is shaped to impart a rough design to underside surface 28 of pin head 26, other patterns being within the purview of embodiments. Preferably, the coining takes place with a single hit of the flattening head 22 onto the pin blank 20 to form the pin head 26. The pin blank may include, for example, Alloy 42 (a Ni—Fe alloy), or Kovar (a Ni—Fe—Co alloy). Coining may take place, for example, for a 0.3 mm diameter Alloy 42 pin, at a temperature of about 25 degrees Celsius and using a coining force of about 150 to about 200 N per pin. Various other combinations of temperatures and coining forces may be used depending on the material and diameter of the pin. The blanks may further be annealed prior to coining, for example where Kovar is used as the pin material, at a temperature between about 780 to about 800 degrees Celsius to soften the material, allowing the use of lower forces. The flattening head 22 may, for example, be made of a ceramic material or a metallic alloy material, and may be shaped either by way of machining or, preferably, by way of etching, other materials and other techniques for shaping the flattening head being within the purview of embodiments. After coining or flattening as shown in FIG. 2c, the flattening head 22 may be withdrawn, the pin 21 may be ejected from the support jig 23, and any necessary cleaning performed, as would be within the knowledge of the skilled person. According to one embodiment, in order to provide for better electrical contact by way of the pin 21, the pin may be coated, for example by way of dip coating, electroless deposition, or using other techniques, with a conductive layer, such as conductive layer 25 shown in FIG. 2d. Preferably, the conductive layer 25 may be made of gold, and may further have a thickness, for example, of about 0.1-0.2 micron.

Referring next to FIG. 2e, a PGA joint formed with pin 21 is depicted. Pin 21 is shown as being mounted onto substrate 30. The pin head 26 is shown as being mounted onto a land pad 32 on a PCB-side surface 34 of substrate 30 using a pin-attach solder joint 36 as shown. As seen in FIG. 2e, the pin-attach solder joint 36 contains relatively fewer voids as compared with the prior art and the pin is substantially upright with respect to the land pad 32.

Advantageously, method embodiments provide a quick, cost-effective technique for making pins having pin heads with topographies on their underside surfaces that allow solder voids and flux volatiles to escape during high temperature reflow processes to attach a die to the package substrate, and in this way substantially prevent pin tilt and improve pin joint reliability. Moreover, method embodiment provides topography on the underside surfaces of pin heads that advantageously allow for volatiles to escape from an underside of the pin during pin attach to substrate lands, in this way bringing about a pin-attach solder joint including fewer voids under the pin and hence improved pin pull strength performance. Additionally, advantageously, method embodiment provides topography on underside surfaces of pin heads that allow increased surface area for the pin-attach solder to wet the pin, and in this way allow for the formation of a robust pin-attach solder joint. A more robust bonding quality, including less voids and more bonding area of the pin head with the substrate land, advantageously tends to restrict a tilting effect of pin attach solder softening on the pin during C4 attach reflow.

The various embodiments described above have been presented by way of example and not by way of limitation. Having thus described in detail embodiments of the present invention it is understood that the invention defined by the appended claims is not to be limited by particular details set forth in the above description, as many variations thereof are possible without departing from the spirit or scope thereof.

What is claimed is:

1. A method of forming a pin adapted to be used in a PGA joint, the method comprising:
providing a pin blank;
forming a pin head by coining an end of the pin blank using a flattening head thereby forming the pin, the pin having a pin stem and the pin head attached to the pin stem, the flattening head being shaped to impart a topography to an underside surface to the pin head that is non-smooth during coining, the topography being adapted to allow gases to escape from a pin-attach solder disposed adjacent to the underside surface.

2. The method of claim 1, wherein the flattening head is made of a ceramic material or of a metallic alloy material.

3. The method of claim 1, wherein coining takes place with a single hit of the flattening head onto the pin blank to form the pin head.

4. The method of claim 1, further including coating the pin with a conductive layer.

5. The method of claim 4, wherein the conductive layer comprises gold.

6. The method of claim 1, wherein the pin is made of material comprising one of Alloy 42 and Kovar.

7. The method of claim 1, further including annealing the pin blank prior to forming a pin head.

8. The method of claim 7, wherein annealing includes annealing at a temperature between about 780 and 800 degrees Celsius.

9. A flattening head of a device to form pins adapted to be used in a PGA joint, the flattening head being configured to form a pin head of the pin by coining an end of a pin blank so as to impart a topography to an underside surface of the pin head that is a non-smooth topography being adapted to allow gases to escape from a pin-attach solder disposed adjacent to the underside surface.

10. The flattening head of claim 11, wherein the flattening head is made of a ceramic material or of a metallic alloy material.
